(19) United States
(12) Patent Application Publication
(10) Pub. No.: US 2025/0218836 A1
(43) Pub. Date: Jul. 3, 2025

(54) CONTAINER TRANSPORTING APPARATUS AND LOGISTICS PROCESSING SYSTEM INCLUDING THE SAME

(71) Applicant: SEMES CO., LTD., Chungcheongnam-do (KR)

(72) Inventors: Geo Chul JEONG, Gyeonggi-do (KR); Byung Kwon LEE, Gyeonggi-do (KR); Yeong Jae CHOE, Gyeonggi-do (KR); Eun Ji CHOI, Gyeonggi-do (KR)

(21) Appl. No.: 18/983,337

(22) Filed: Dec. 16, 2024

(30) Foreign Application Priority Data
Dec. 28, 2023 (KR) 10-2023-0193926

(51) Int. Cl. H01L 21/677; H01F 7/02

(52) U.S. Cl. CPC H01L 21/67727; H01F 7/02; H01L 21/67706; H01L 21/6773

(57) ABSTRACT

A container transporting apparatus equipped with a non-contact gear and a logistics processing system including the same are provided. The logistics processing system is installed in a semiconductor manufacturing plant and includes a container transporting apparatus for transporting a container containing a plurality of substrates; a container storage apparatus for storing the container therein; and a control device configured to control each of the container transporting apparatus and the container storage apparatus, wherein the container transporting apparatus includes a non-contact gear.

### CROSS-REFERENCE TO RELATED APPLICATION

This application claims priority from Korean Patent Application No. 10-2023-0193926 filed on Dec. 28, 2023 in the Korean Intellectual Property Office, and all the benefits accruing therefrom under 35 U.S.C. 119, the contents of which in its entirety are herein incorporated by reference.

### BACKGROUND

### Field

The present disclosure relates to a container transporting apparatus installed in a semiconductor manufacturing plant and a logistics processing system including the same.

### Description of Related Art

An OHT (Overhead Hoist Transport) plays a role in transporting articles to a destination within a semiconductor manufacturing plant. For example, the OHT may transport a FOUP (Front Opening Unified Pod) to a location where a substrate treatment apparatus is located. A plurality of substrates (wafers) may be stored in the FOUP.

The OHT may move to a destination along a rail installed on a ceiling of the semiconductor manufacturing plant. The OHT may include a reducer to control a speed of the OHT while the OHT is driving. However, since the reducer installed in the OHT is a mechanical reducer and operates via teeth contacting each other, particles may be generated due to wear of the teeth.

### SUMMARY

A technical purpose to be achieved in accordance with the present disclosure is to provide a container transporting apparatus equipped with a non-contact gear and a logistics processing system including the same.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

A logistics processing system according to some embodiments of the present disclosure for achieving the above technical purpose is installed in a semiconductor manufacturing plant, and includes a container transporting apparatus for transporting a container containing a plurality of substrates; a container storage apparatus for storing the container therein; and a control device configured to control each of the container transporting apparatus and the container storage apparatus, wherein the container transporting apparatus includes a non-contact gear.

A container transporting apparatus according to some embodiments of the present disclosure for achieving the above technical purpose is configured to transport a container containing a plurality of substrates in a semiconductor manufacturing plant, and includes a driving motor for generating a driving force; a driving wheel for generating a rotational force and moving the container transporting apparatus under the rotational force; a driving shaft for transmitting the driving force to the driving wheel; and an electronic gear coupled to the driving shaft and the driving wheel, wherein the electronic gear is embodied as a non-contact gear using a magnet.

A logistics processing system according to some embodiments of the present disclosure for achieving the above technical purpose is installed in a semiconductor manufacturing plant, and includes a container transporting apparatus for transporting a container containing a plurality of substrates; a container storage apparatus for storing the container therein; and a control device configured to control each of the container transporting apparatus and the container storage apparatus, wherein the container transporting apparatus includes: a driving motor for generating a driving force; a driving wheel for generating a rotational force and moving the container transporting apparatus under the rotational force; a driving shaft for transmitting the driving force to the driving wheel; and an electronic gear coupled to the driving shaft and the driving wheel, wherein the electronic gear is embodied as a non-contact gear using a magnet, wherein the electronic gear includes: a first core portion surrounding the driving shaft; a first magnet portion surrounding the driving shaft and adjacent to the first core portion; a second core portion surrounding the driving shaft and adjacent to the first magnet portion, wherein the second core portion includes a plurality of rods; a second magnet portion surrounding the driving shaft and adjacent to the second core portion; and a third core portion surrounding the driving shaft and adjacent to the second magnet portion, wherein each of the plurality of rods extends in a direction different from a longitudinal direction of the driving shaft, wherein a number of the plurality of rods is determined based on a number of pole pairs of the magnets included in the first magnet portion and a number of pole pairs of the magnets included in the second magnet portion, wherein a rotation speed of the second magnet portion is determined based on a rotation speed of the first magnet portion, a number of pole pairs of the magnets included in the first magnet portion, and a number of pole pairs of the magnets included in the second magnet portion.

Specific details of other embodiments are included in the detailed descriptions and diagrams.

### BRIEF DESCRIPTION OF DRAWINGS

The above and other aspects and features of the present disclosure will become more apparent by describing in detail embodiments thereof with reference to the attached drawings, in which:

FIG. 1 is a diagram schematically illustrating an internal configuration of a logistics processing system according to an embodiment of the present disclosure;

FIG. 2 is an example diagram schematically illustrating a structure of a container transporting apparatus constituting a logistics processing system according to an embodiment of the present disclosure;

FIG. 3 is an example diagram schematically illustrating an installation shape of a container transporting apparatus in a semiconductor manufacturing plant;

FIG. 4 is an example diagram for illustrating a driver of a container transporting apparatus according to an embodiment of the present disclosure;

FIG. 5 is a perspective view for illustrating an internal structure of an electronic gear constituting a driver of a container transporting apparatus according to a first embodiment of the present disclosure;

FIG. 6 is a cross-sectional view for illustrating the internal structure of the electronic gear constituting the driver of the container transporting apparatus according to the first embodiment of the present disclosure;

FIG. 7 is an exploded perspective view for illustrating an internal structure of an electronic gear constituting a driver of a container transporting apparatus according to a second embodiment of the present disclosure; and

FIG. 8 is an assembled perspective view for illustrating the internal structure of the electronic gear constituting the driver of the container transporting apparatus according to the second embodiment of the present disclosure.

### DETAILED DESCRIPTIONS

Hereinafter, embodiments of the present disclosure will be described in detail with reference to the attached drawings. Identical reference numerals are used for identical components in the drawings, and redundant descriptions thereof are omitted.

The present disclosure relates to a container transporting apparatus and a logistics processing system including the same. The container transporting apparatus may be an apparatus equipped with a non-contact gear. Hereinafter, the logistics processing system including the container transporting apparatus will be described first, and then the container transporting apparatus equipped with the non-contact gear will be described.

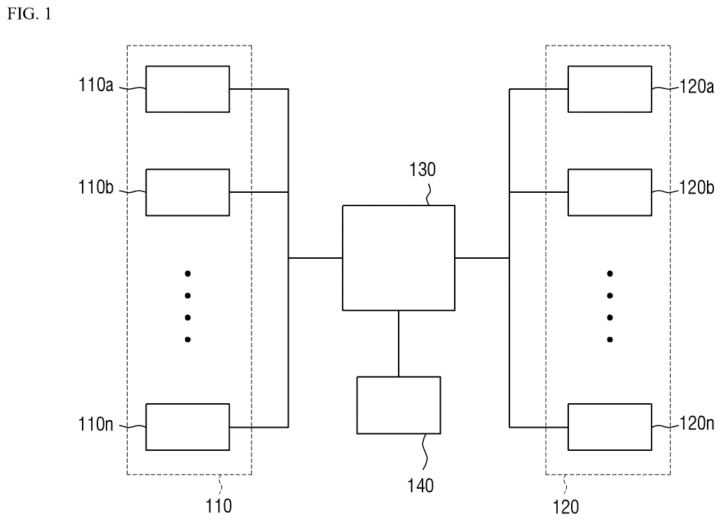

FIG. 1 is a diagram schematically illustrating an internal configuration of the logistics processing system according to one embodiment of the present disclosure. Referring to FIG. 1, a logistics processing system 100 may be configured to include a container transporting apparatus 110, a container storage apparatus 120, a control device 130, and database 140.

The logistics processing system 100 may be installed in a semiconductor manufacturing plant. The logistics processing system 100 may include a plurality of container transporting apparatuses 110 and a plurality of container storage apparatuses 120. The logistics processing system 100 may be constructed to provide a logistics automation service in the semiconductor manufacturing plant.

Herein, a first direction D1 and a second direction D2 define a plane in a horizontal direction. For example, the first direction D1 may be a forward/backward direction, and the second direction D2 may be a left/right direction. Alternatively, the first direction D1 may be a left/right direction, and the second direction D2 may be a forward/backward direction. The third direction D3 may be a height direction, and may be a direction perpendicular to the plane defined by the first direction D1 and the second direction D2. The third direction D3 may be a vertical direction.

The container transporting apparatus 110 serves to transport a container to a destination. For example, the container transporting apparatus 110 may be embodied as an OHT (Overhead Hoist Transport).

The container transporting apparatus 110 may travel on a path (e.g., a rail) installed on a ceiling of the semiconductor manufacturing plant and may be configured to transport the container to the destination. The container transporting apparatus 110 may transport the container to a process facility (e.g., various process chambers such as a deposition process chamber, an etching process chamber, a cleaning process chamber, and a heat treatment process chamber) where a semiconductor manufacturing process is performed. A plurality of container transporting apparatuses 110a, 110b, . . . , 110n may be disposed within the semiconductor manufacturing plant.

When the container transporting apparatus 110 transports the container to the facility where the semiconductor manufacturing process is performed, a plurality of substrates (e.g., wafers) may be stored in the container. For example, the container may be embodied as a FOUP (Front Opening Unified Pod).

The container transporting apparatus 110 may operate under control of the control device 130. Although not shown in FIG. 1, the container transporting apparatus 110 may include a communication module for wired/wireless communication with the control device 130 such that the container transporting apparatus 110 may operate under control of the control device 130.

In another example, the container transporting apparatus 110 may operate autonomously without being controlled by the control device 130. In this case, a plurality of sensors may be installed around a movement path of the container transporting apparatus 110 and may provide information so that the plurality of container transporting apparatus 110a, 110b, . . . , 110n disposed in the semiconductor manufacturing plant do not collide with each other. The plurality of container transporting apparatus 110a, 110b, . . . , 110n may communicate with each other so as not to collide with each other.

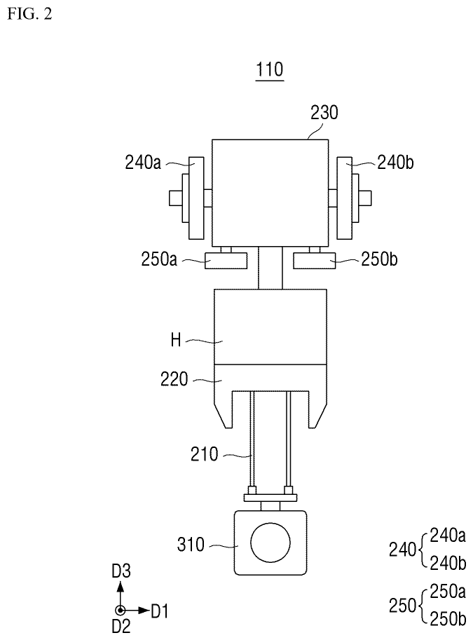

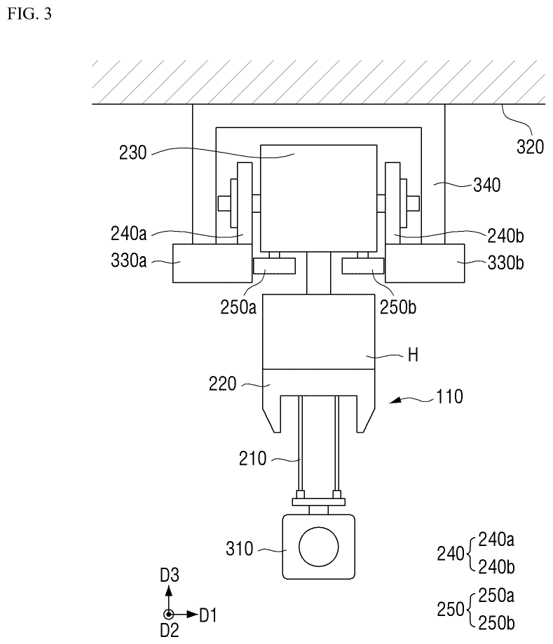

FIG. 2 is an example diagram schematically illustrating a structure of a container transporting apparatus constituting a logistics processing system according to one embodiment of the present disclosure. FIG. 3 is an example diagram schematically illustrating an installation shape of a container transporting apparatus in a semiconductor manufacturing plant. According to FIG. 2 and FIG. 3, the container transporting apparatus 110 may be configured to include a gripping module 210, a vertically-moving module 220, a driving module 230, a driving wheel 240, and a guide wheel 250.

The gripping module 210 is configured to grip a container 310. The gripping module 210 may descend to a location (e.g., an Equipment Front End Module (EFEM)) where the container 310 is positioned to grip the container 310 in order to transport the container 310 to a destination. The gripping module 210 may be embodied as, for example, a hand gripper.

The vertically-moving module 220 is configured to vertically move the gripping module 210. The vertically-moving module 220 may lower the gripping module 210 from a ceiling 320 toward a ground so that the gripping module 210 may grip the container 310. When the gripping module 210 has gripped the container 310, the vertically-moving module 220 may raise the gripping module 210 again to the ceiling 320. The vertically-moving module 220 may be embodied as, for example, a hoist.

When the container 310 has been loaded on the container transporting apparatus 110 using the gripping module 210 and the vertically-moving module 220, the container transporting apparatus 110 may transport the container 310 to the destination. When the container transporting apparatus 110 reaches the destination, the vertically-moving module 220 lowers the gripping module 210 again. Thus, the gripping module 210 releases the container 310 seated on a load port module of the EFEM, so that the plurality of substrates stored in the container 310 may be transferred to a process facility where a next semiconductor manufacturing process is performed.

Meanwhile, although not shown in FIG. 2 and FIG. 3, the container transporting apparatus 110 may include a storage module that provides a storage space instead of the gripping module 210. The storage module may be formed in a shape (for example, a basket shape) in which an upper portion is open to store the container 310 therein, or may be formed in a shape (for example, a cabinet shape) in which a door is installed at an open side portion to open or close the open side portion.

The driving module 230 controls the driving wheel 240 that travels along a travel path (e.g., a pair of rails 330a and 330b) installed on the ceiling 320 of the semiconductor manufacturing plant. For this purpose, although not shown in FIG. 2 and FIG. 3, the driving module 230 may include a driving motor, a driving shaft, etc. In this regard, the driving motor may play a role in generating a driving force, and the driving shaft may play a role in providing the driving force generated by the driving motor to the driving wheel 240.

The driving wheel 240 is a rotating body that rotates using the driving force provided by the driving module 230. Under the rotation thereof, the container transporting apparatus 110 may travel on the pair of rails 330 and 330b. The driving wheel 240 may include a pair of wheels 240a and 240b so as to be able to travel on the rails 330a and 330b, respectively. In this case, the pair of driving wheels 240a and 240b may be respectively coupled to both opposing side surfaces of the drive module 230.

The guide wheel 250 prevents the container transporting apparatus 110 from being removed from the rails 330a and 330b when the container transporting apparatus 110 travels on the pair of rails 330a and 330b. The guide wheel 250 may include a pair of wheels 250a and 250b in a similar manner to the drive wheel 240. The pair of wheels 250a and 250b may be respectively installed on both opposing ends of a lower surface of the driving module 230 and may be installed in a perpendicular manner to the driving wheels 240a and 240b.

The container transporting apparatus 110 may include a speed control unit, a position control unit, etc. In this regard, the speed control unit may play a role of controlling the rotation speed of the driving wheel 240, and the position control unit may play a role of correcting the position of the container 310.

The position control unit may include a slider and a rotator. The slider may play a role of moving the container 310 up and down or left and right, and the rotator may play a role of rotating the container 310 clockwise or counterclockwise.

In order to provide the movement path of the container transporting apparatus 110, a rail assembly including the pair of rails 330a and 330b and a rail support module 340 may be installed on the ceiling 320 of the semiconductor manufacturing plant. The pair of rails 330a and 330b may provide a travel path of the container transporting apparatus 110 as described above, and may be coupled to both opposing ends of the rail support module 340 fixed to the ceiling 320 of the semiconductor manufacturing plant.

Each of the pair of rails 330a and 330b may be constructed to include various types of sections, such as a straight section, a curved section, an inclined section, a branched section, and an intersection section, depending on a layout of the ceiling 320 in the semiconductor manufacturing plant. However, the present embodiment is not limited thereto. Each of the pair of rails 330a and 330b may be constructed to include only one type of a section among the various types of sections.

The rail support module 340 is fixed to the ceiling 320 of the semiconductor manufacturing plant and serves to support the pair of rails 330a and 330b. The rail support module 340 may be installed on the ceiling 320 of the semiconductor manufacturing plant so as to have a cap shape in a bottom view from a ground.

Description will be made with referring again to FIG. 1.

The container storage apparatus 120 may store therein the container 310. For this purpose, the container storage apparatus 120 may include a storage module therein. The storage module may be configured in multiple stages. At least one container 310 may be stored in each stage, and accordingly, the storage module may store a plurality of containers 310 therein. The storage module may be configured in the multiple stages arranged in the third direction D3. However, the present disclosure is not limited thereto, and the storage module may also be configured in the multiple stages arranged in the first direction D1. Alternatively, the storage module may be configured in the multiple stages arranged in either the first direction D1 or the second direction D2 and the third direction D3. The container storage apparatus 120 may include a plurality of container storage apparatuses 120a, 120b, . . . , 120n in a similar manner to the container transporting apparatus 110.

The container storage apparatus 120 may be installed in an internal space of a semiconductor manufacturing plant. The container storage apparatus 120 may be installed on a floor of a semiconductor manufacturing plant. The container storage apparatus 120 may be embodied as a stocker. The container storage apparatus 120 may be installed on the ceiling of a semiconductor manufacturing plant. The container storage apparatus 120 may be embodied as a side track buffer (STB).

The control device 130 may be configured to control the plurality of container transporting apparatuses 110a, 110b, . . . , 110n. The control device 130 may be configured to independently control each of the container transporting apparatuses 110a, 110b, . . . , 110n so that each of the container transporting apparatuses 110a, 110b, . . . , 110n may safely transport the container 310 to a destination (e.g., various process facilities where a semiconductor manufacturing process is performed).

The control device 130 may be configured to transmit a signal such as a start command, a stop command, an acceleration command, a deceleration command, etc. to the container transporting apparatus 110 to control movement of the container transporting apparatus 110. Furthermore, the control device 130 may be configured to provide necessary information (e.g., a route to the destination) to the container transporting apparatus 110 through wired/wireless communication with the container transporting apparatus 110.

In order to perform the above roles, the control device 130 may be configured to recognize a location of each of the container transporting apparatuses 110a, 110b, . . . , 110n. In this case, the control device 130 may be configured to utilize the plurality of sensors installed around the pair of rails 330a and 330b or to utilize a result obtained by communicating with each of the container transporting apparatuses 110a, 110b, . . . , 110n via wired/wireless communication.

When the control device 130 is configured to utilize the plurality of sensors installed around the pair of rails 330a and 330b, the control device 130 may be configured to recognize the location of each of the container transporting apparatuses 110a, 110b, . . . , 110n by utilizing identification information (e.g., a serial number) of a corresponding sensor, location information (e.g., two-dimensional coordinate information (x, y) or three-dimensional coordinate information (x, y, z) of the corresponding sensor, identification information of the container storage apparatus 120 that has passed by the corresponding sensor, etc. When the control device 130 is configured to utilize the result obtained by communicating with each of the container transporting apparatuses 110a, 110b, . . . , 110n via wired/wireless communication, each of the container transporting apparatuses 110a, 110b, . . . , 110n may measure a current position thereof on its own, and the control device 130 may be configured to recognize the position of each of the container transporting apparatuses 110a, 110b, . . . , 110n through communication with each of the container transporting apparatuses 110a, 110b, . . . , 110n.

The control device 130 may be configured to include a processor that executes control of each of the components constituting the logistics processing system 100, a communication unit which communicates with each of the components in a wired manner or wirelessly, one or more instructions related to a function or an operation for controlling each of the components, and a memory means that stores therein processing recipes, various data, etc. including the instructions. The control device 130 may be configured to further include a user interface including an input means used for an operator to perform a command input manipulation, etc. to manage the logistics processing system 100, and an output means for visualizing and displaying an operating status of the logistics processing system 100. The control device 130 may be embodied as a computing device for data processing and analysis, command transmission, etc.

The instructions may be provided in a form of a computer program or an application. The computer program may be stored in a computer-readable recording medium including one or more instructions. The instructions may include codes generated by a compiler, codes that may be executed by an interpreter, etc. The memory means may be embodied as one or more storage media selected from among flash memory, HDD, SSD, card type memory, RAM, SRAM, ROM, EEPROM, PROM, magnetic memory, magnetic disk, and optical disk.

The database 140 stores therein information required for the control device 130 to control the plurality of container transporting apparatuses 110a, 110b, . . . , 110n. The database 140 may be installed inside the control device 130 or may be installed separately outside the control device 130 and be connected thereto in a wired/wireless manner so as to provide information required by the control device 130.

As described above, the container transporting apparatus 110 may be equipped with a non-contact gear. The container transporting apparatus 110 may be equipped with a non-contact electronic gear. The container transporting apparatus 110 may be equipped with a non-contact electronic gear based on a magnetic flux modulation effect.

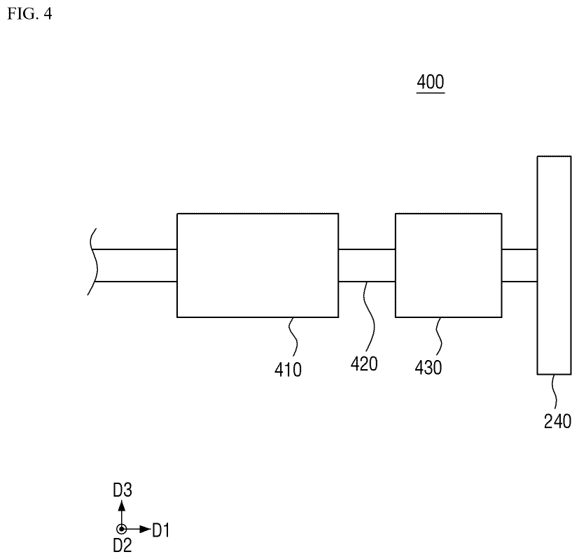

FIG. 4 is an example diagram for illustrating a driver of a container transporting apparatus according to one embodiment of the present disclosure. Referring to FIG. 4, the driver 400 may be configured to include a driving wheel 240, a driving motor 410, a driving shaft 420, and an electronic gear 430.

The container transporting apparatus 110 may travel along the rails 330a and 330b installed on the ceiling of the semiconductor manufacturing plant and transport the container 310 to the destination. The container transporting apparatus 110 may travel on the rail 330a and 330b under the rotation of the driving wheel 240. The driving wheel 240 may be embodied as a rotating body.

The driving motor 410 may generate the driving force using electric energy upon receiving the electric energy. Although not shown in FIG. 4, the driving motor 410 may receive electric energy through a power source. The driving motor 410 may receive the electric energy through the power source installed in the semiconductor manufacturing plant. Alternatively, the driving motor 410 may receive the electric energy through a battery installed in the container transporting apparatus 110. The driving force generated by the driving motor 410 may be used to rotate the driving wheel 240. The driving motor 410 may be installed in the driving module 230 as described with reference to FIG. 2.

The driving shaft 420 may provide the driving force generated by the driving motor 410 to the driving wheel 240. The driving shaft 420 may be directly connected to the driving motor 410. The driving shaft 420 may directly receive the driving force from the driving motor 410. The driving shaft 420 may be indirectly connected to the driving wheel 240. The driving shaft 420 may transmit the driving force to the driving wheel 240 through the electronic gear 430. The driving shaft 420 may be provided in a form of a shaft.

The electronic gear 430 may connect the driving motor 410 and the driving wheel 240 to each other. The electronic gear 430 may be indirectly connected to the driving motor 410 through the driving shaft 420 and may be directly connected to the driving wheel 240. The electronic gear 430 may be disposed between the driving shaft 420 and the driving wheel 240. The electronic gear 430 may not directly contact each of the driving shaft 420 and the driving wheel 240. When the driving wheel 240 rotates under the driving force generated by the driving motor 410, the electronic gear 430 provides the driving force of the driving motor 410 to the driving wheel 240. Since there is no direct contact between each of the driving shaft 420 and the driving wheel 240 and the electronic gear 430, a wear of the electronic gear 430 may not occur while transferring the driving force of the driving motor 410 to the driving wheel 240.

Therefore, particles caused by the wear may be reduced, and thus, contamination of the facility in the semiconductor manufacturing plant including the container transporting apparatus 110 due to the particles may be reduced.

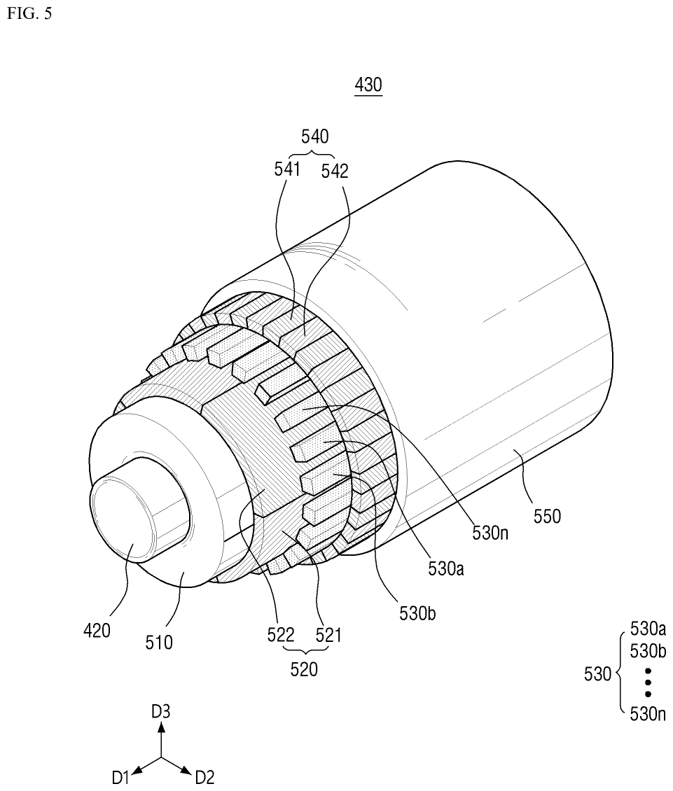

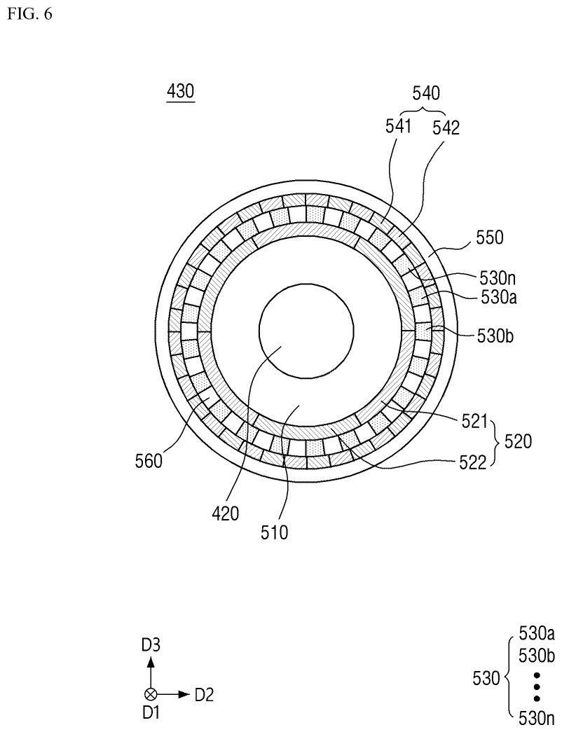

The electronic gear 430 may act as a reducer in the driver of the container transporting apparatus 110. The electronic gear 430 may be embodied as a non-contact gear to minimize production of particles. In particular, the electronic gear 430 may be embodied as a non-contact gear based on the magnetic flux modulation effect. FIG. 5 is a perspective view for illustrating an internal structure of the electronic gear constituting the driver of the container transporting apparatus according to a first embodiment of the present disclosure. FIG. 6 is a cross-sectional view for illustrating the internal structure of the electronic gear constituting the driver of the container transporting apparatus according to the first embodiment of the present disclosure.

Referring to FIG. 5 and FIG. 6, the electronic gear 430 may be configured to include a first core portion 510, a first magnet portion 520, a second core portion 530, a second magnet portion 540, and a third core portion 550.

The first core portion 510 may act as an inner core and may be formed to surround the driving shaft 420. The first core portion 510 and the driving shaft 420 may be concentric with each other. The first core portion 510 may rotate at a high speed. The first core portion 510 may be embodied as a high-speed rotor.

The first magnet portion 520 may act as an inner magnet and may be formed to surround the first core portion 510. The first magnet portion 520 may be composed of a plurality of permanent magnets. However, the present disclosure is not limited thereto, and the first magnet portion 520 may be composed of a plurality of electromagnets. Alternatively, the first magnet portion 520 may be composed of a combination of permanent magnets and electromagnets.

The plurality of permanent magnets may include a magnet 521 having a first polarity and a magnet 522 having a second polarity. A combination of the magnets 521 having the first polarity and the magnets 522 having the second polarity may constitute a circle. This circle and each of the driving shaft 420 and the first core portion 510 may be concentric with each other. The magnet 521 having the first polarity may have one of the N-pole polarity and the S-pole polarity. The magnet 522 having the second polarity may have the other of the N-pole polarity and the S-pole polarity. Each of the magnet 521 having the first polarity and the magnet 522 having the second polarity may include a plurality of magnets. The number of the magnets 521 having the first polarity may be equal to the number of the magnets 522 having the second polarity.

The second core portion 530 may act as a pole piece and may be formed to surround the first magnet portion 520. The second core portion 530 may rotate at a low speed. The second core portion 530 may be embodied as a low-speed rotor. The second core portion 530 may convert a high speed and low-torque rotation of the first core portion 510 into a low-speed and high-torque rotation. The second core portion 530 may be embodied as a flux modulated core.

The second core portion 530 may include a plurality of rods 530a, 530b, . . . , 530n. The plurality of rods 530a, 530b, . . . , 530n may be arranged so as to be spaced from each other by a predetermined spacing. The plurality of rods 530a, 530b, . . . , 530n of the second core portion 530 may be arranged in a circular manner. Thus, the arrangement thereof may constitute a circle. The circle and the driving shaft 420 may be concentric with each other. That is, the second core portion 530, the driving shaft 420 and the first core portion 510 may be concentric with each other. An air gap may be formed between adjacent ones of the rod 530a, 530b, . . . , 530n.

When the second core portion 530 is composed of the plurality of rods 530a, 530b, . . . , 530n, the number of rods 530a, 530b, . . . , 530n may be determined based on the number of pole pairs of the inner permanent magnets and the number of pole pairs of the outer permanent magnets. That is, the number of rods 530a, 530b, . . . , 530n may be determined based on the number of pole pairs of magnets 521 and 522 included in the first magnet portion 520 and the number of pole pairs of magnets 541 and 542 included in the second magnet portion 540. The number of rods 530a, 530b, . . . , 530n may be determined as a sum of the number of pole pairs of magnets 521 and 522 included in the first magnet portion 520 and the number of pole pairs of magnets 541 and 542 included in the second magnet portion 540.

As described above, the first core portion 510 may rotate at the high speed. On the other hand, the second core portion 530 may rotate at the low speed. The rotation speed of the second core portion 530 may be different from the rotation speed of the first core portion 510. The rotation speed of the second core portion 530 may be lower than the rotation speed of the first core portion 510. The rotation speed of the second core portion 530 may be determined based on the rotation speed of the first core portion 510. The rotation speed of the second core portion 530 may be determined based on a value obtained by performing calculation based on the number of pole pairs of the magnets 521 and 522 included in the first magnet portion 520, the number of pole pairs of the magnets 541 and 542 included in the second magnet portion 540, and the rotation speed of the first core portion 510. When the number of pole pairs of the magnets 521 and 522 included in the first magnet portion 520 is defined as A, the number of pole pairs of the magnets 541 and 542 included in the second magnet portion 540 is defined as B, the rotation speed of the first core portion 510 is defined as C, and the rotation speed of the second core portion 530 is defined as D, the rotation speed of the second core portion 530 may be determined based on a following Equation.

D=−(A/B)*C

In this regard, − means that the second core portion 530 rotates in a different direction from the rotation direction of the first core portion 510.

The second magnet portion 540 may act as an outer magnet and be formed to surround the second core portion 530. The second magnet portion 540 may be composed of a plurality of permanent magnets. However, the present disclosure is not limited thereto, and the second magnet portion 540 may be composed of a plurality of electromagnets. Alternatively, the second magnet portion 540 may be composed of a combination of permanent magnets and electromagnets.

The plurality of permanent magnets may include a magnet 541 having a first polarity and a magnet 542 having a second polarity. A combination of the magnets 541 having the first polarity and the magnets 542 having the second polarity may constitute a circle. This circle, the driving shaft 420, the first core portion 510 and the second core portion 530 may be concentric with each other. The magnet 541 having the first polarity may have one of the N-pole polarity and the S-pole polarity. The magnet 542 having the second polarity may have the other of the N-pole polarity and the S-pole polarity. Each of the magnet 541 having the first polarity and the magnet 542 having the second polarity may include a plurality of magnets. The number of the magnets 541 having the first polarity may be equal to the number of the magnets 542 having the second polarity.

The magnet 521 having the first polarity of the first magnet portion 520 may include a plurality of magnets 521. Likewise, the magnet 541 having the first polarity of the second magnet portion 540 and may include a plurality of magnets 541. The number of the magnets 541 having the first polarity of the second magnet portion 540 may be greater than the number of the magnets 521 having the first polarity of the first magnet portion 520. A size of each of the magnets 541 having the first polarity of the second magnet portion 540 may be equal to a size of each of the magnets 521 having the first polarity of the first magnet portion 520. However, the present disclosure is not limited thereto, and the size of each of the magnets 541 having the first polarity of the second magnet portion 540 may be smaller or larger than the size of each of the magnets 521 having the first polarity of the first magnet portion 520.

The third core portion 550 may act as an outer core and may be formed to surround the second magnet portion 540. The third core portion 550, the driving shaft 420, the first core portion 510, and the second core portion 530 may be concentric with each other.

The driving motor 410 may be connected to the driving shaft 420 located at the innermost area. The first core portion 510 may be connected to the driving motor 410 via the driving shaft 420. The second core portion 530 may be coupled to the driving wheel 240. The first magnet portion 520 may be disposed inwardly of the second core portion 530. That is, the first magnet portion 520 may be located between the first core portion 510 and the second core portion 530. Furthermore, the second magnet portion 540 may be disposed outwardly of the second core portion 530. That is, the second magnet portion 540 may be positioned between the second core portion 530 and the third core portion 550. The second core portion 530 may generate a magnetic flux modulation effect.

The electronic gear 430 may be embodied as a deceleration device under a magnetic field and magnetic resistance. The electronic gear 430 may be constructed as a non-contact electronic gear system utilizing the magnetic flux modulation effect. The electronic gear 430 may operate under an attractive force and a repulsive force of the permanent magnet, and has a non-contact structure, does not wear out, and does not require oil, and thus has a great advantage in terms of maintenance. The container transporting apparatus 110 may have the electronic gear 430 as a deceleration device and thus may be expected to have effects such as particle generation reduction, maintenance cost reduction, and reliability improvement.

As described above, the second core portion 530 may include the plurality of rods 530a, 530b, . . . , 530n. Each of the plurality of rods 530a, 530b, . . . , 530n may extend along a longitudinal direction of the driving shaft 420. For example, each of the plurality of rods 530a, 530b, . . . , 530n may extend in the first direction D1. However, the present disclosure is not limited thereto, and each of the plurality of rods 530a, 530b, . . . , 530n may extend along a radial direction of the driving shaft 420. For example, each of the plurality of rods 530a, 530b, . . . , 530n may extend in the third direction D3.

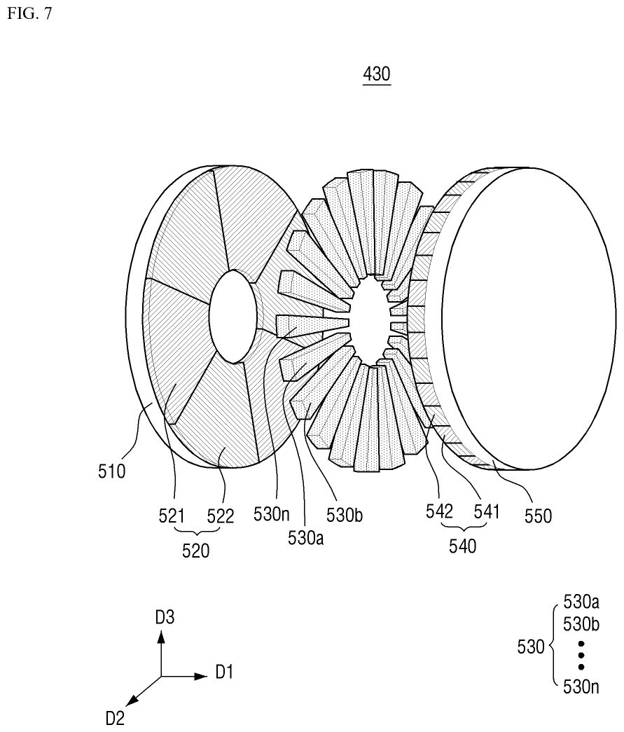

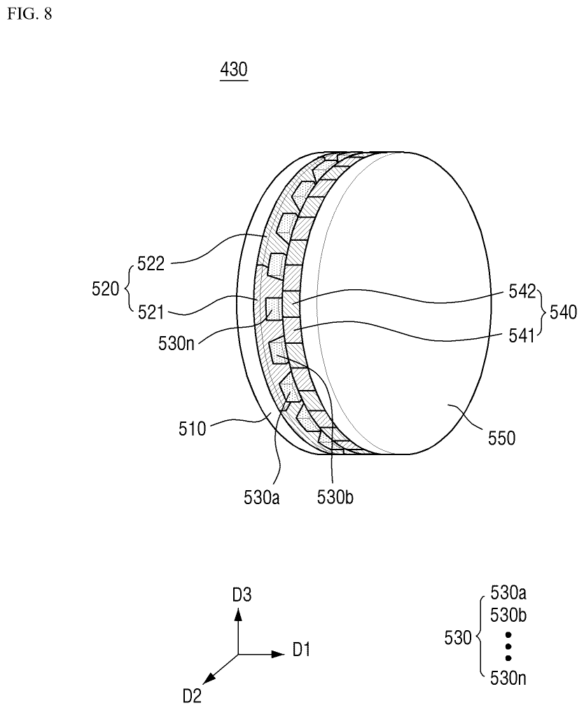

FIG. 7 is an exploded perspective view for illustrating an internal structure of the electronic gear constituting the driver of the container transporting apparatus according to a second embodiment of the present disclosure. FIG. 8 is an assembled perspective view for illustrating the internal structure of the electronic gear constituting the driver of the container transporting apparatus according to the second embodiment of the present disclosure.

Hereinafter, the description of the duplicate contents with those of the electronic gear 430 according to the first embodiment as described with reference to FIG. 5 and FIG. 6 will be omitted, and only differences therebetween will be described.

The first core portion 510 may be formed to surround the driving shaft 420. The first magnet portion 520 may be formed to surround the driving shaft 420 in a similar manner to the first core portion 510 and may be disposed adjacent to the first core portion 510 in a length direction of the driving shaft. The second core portion 530 may be formed to surround the driving shaft 420 in a similar manner to the first core portion 510 and the first magnet portion 520 and may be disposed adjacent to the first magnet portion 520 in the length direction of the driving shaft. The second magnet portion 540 may be formed to surround the driving shaft 420 in a similar manner to the first core portion 510, the first magnet portion 520 and the second core portion 530 and may be disposed adjacent to the second core portion 530 in the length direction of the driving shaft. The third core portion 550 may be formed to surround the driving shaft 420 in a similar manner to the first core portion 510, the first magnet portion 520, the second core portion 530, and the second magnet portion 540, and may be disposed adjacent to the second magnet portion 540 in the length direction of the driving shaft.

The first core portion 510 may be closer to the driving motor 410 than the third core portion 550 may be. The first core portion 510, the first magnet portion 520, the second core portion 530, the second magnet portion 540, and the third core portion 550 may be closer to the driving motor 410 in this order. The third core portion 550 may be closer to the driving wheel 240 than the first core portion 510 may be. The third core portion 550, the second magnet portion 540, the second core portion 530, the first magnet portion 520, and the first core portion 510 may be closer to the driving wheel 240 in this order.

The second core portion 530 may be coupled to the driving wheel 240. Each of the plurality of rods 530a, 530b, . . . , 530n may be connected to the driving wheel 240. In the case of FIG. 5 and FIG. 6, the plurality of rods 530a, 530b, . . . , 530n may extend in the longitudinal direction of the driving shaft 420. Each of the plurality of rods 530a, 530b, . . . , 530n may be coupled to the driving wheel 240 meeting an extension line in a longitudinal direction of each of the plurality of rods 530a, 530b, . . . , 530n.

In the case of FIG. 7 and FIG. 8, each of the plurality of rods 530a, 530b, . . . , 530n may extend in a direction different from the longitudinal direction of the driving shaft 420. The third core portion 550 may be coupled to the driving wheel 240. However, the present disclosure is not limited thereto, and the second core portion 530 may also be coupled to the driving wheel 240. In this case, each of the plurality of rods 530a, 530b, . . . , 530n may extend in a direction perpendicular to the longitudinal direction of the driving shaft 420. Each of the plurality of rods 530a, 530b, . . . , 530n may be bent and then extend. Each of the plurality of rods 530a, 530b, . . . , 530n may be coupled to the driving wheel 240 meeting an extension line in a perpendicular direction to a longitudinal direction of each of the plurality of rods 530a, 530b, . . . , 530n. The plurality of rods 530a, 530b, . . . , 530n may be spaced apart from each other, and an air gap may be formed between adjacent ones of the plurality of rods 530a, 530b, . . . , 530n.

Although some embodiments of the present disclosure have been described above with reference to the accompanying diagrams, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

What is claimed is:

1. A logistics processing system installed in a semiconductor manufacturing plant, the logistics processing system comprising:
a container transporting apparatus for transporting a container containing a plurality of substrates;
a container storage apparatus for storing the container therein; and
a control device configured to control each of the container transporting apparatus and the container storage apparatus,
wherein the container transporting apparatus includes a non-contact gear.

2. The logistics processing system of claim 1, wherein the container transporting apparatus includes:
a driving motor for generating a driving force;
a driving wheel for generating a rotational force and moving the container transporting apparatus under the rotational force;
a driving shaft for transmitting the driving force to the driving wheel; and
an electronic gear coupled to the driving shaft and the driving wheel, wherein the electronic gear is embodied as a non-contact gear using a magnet.

3. The logistics processing system of claim 2, wherein the electronic gear acts as a reducer.

4. The logistics processing system of claim 2, wherein the electronic gear includes:
a first core portion surrounding the driving shaft;
a first magnet portion surrounding the driving shaft and adjacent to the first core portion;
a second core portion surrounding the driving shaft and adjacent to the first magnet portion;
a second magnet portion surrounding the driving shaft and adjacent to the second core portion; and
a third core portion surrounding the driving shaft and adjacent to the second magnet portion.

5. The logistics processing system of claim 4, wherein the first core portion rotates at a first speed,
wherein the second core portion rotates at a second speed different from the first speed.

6. The logistics processing system of claim 5, wherein the second speed is lower than the first speed.

7. The logistics processing system of claim 4, wherein the first magnet portion includes:
a plurality of first magnets having a first polarity; and
a plurality of second magnets having a second polarity,
wherein the second magnet portion includes:
a plurality of third magnets having the first polarity; and
a plurality of fourth magnets having the second polarity.

8. The logistics processing system of claim 7, wherein a total number of the third magnets and the fourth magnets are greater than a total number of the first magnets and the second magnets.

9. The logistics processing system of claim 4, wherein the second core portion includes a plurality of rods.

10. The logistics processing system of claim 9, wherein each of the plurality of rods extends in a direction different from a longitudinal direction of the driving shaft.

11. The logistics processing system of claim 9, wherein the plurality of rods are spaced apart from each other, and an air gap is formed between adjacent ones of the plurality of rods.

12. The logistics processing system of claim 9, wherein a number of the plurality of rods is determined based on a number of pole pairs of the magnets included in the first magnet portion and a number of pole pairs of the magnets included in the second magnet portion.

13. The logistics processing system of claim 4, wherein a rotation speed of the second magnet portion is determined based on a rotation speed of the first magnet portion, a number of pole pairs of the magnets included in the first magnet portion, and a number of pole pairs of the magnets included in the second magnet portion.

14. The logistics processing system of claim 4, wherein the first core portion is coupled to the driving shaft,
wherein the second core portion is coupled to the driving wheel.

15. The logistics processing system of claim 4, wherein the second core portion and the first core portion rotate in different directions.

16. The logistics processing system of claim 4, wherein the third core portion is closer to the driving wheel than each of the first core portion and the second core portion is.

17. The logistics processing system of claim 2, wherein the electronic gear includes:
a first core portion surrounding the driving shaft;
a first magnet portion surrounding the first core portion;
a second core portion surrounding the first magnet portion;
a second magnet portion surrounding the second core portion; and
a third core portion surrounding the second magnet portion.

18. A container transporting apparatus for transporting a container containing a plurality of substrates in a semiconductor manufacturing plant, the apparatus comprising:
a driving motor for generating a driving force;
a driving wheel for generating a rotational force and moving the container transporting apparatus under the rotational force;
a driving shaft for transmitting the driving force to the driving wheel; and
an electronic gear coupled to the driving shaft and the driving wheel, wherein the electronic gear is embodied as a non-contact gear using a magnet.

19. The logistics processing system of claim 18, wherein the electronic gear includes:
a first core portion surrounding the driving shaft;
a first magnet portion surrounding the driving shaft and adjacent to the first core portion;
a second core portion surrounding the driving shaft and adjacent to the first magnet portion;
a second magnet portion surrounding the driving shaft and adjacent to the second core portion; and
a third core portion surrounding the driving shaft and adjacent to the second magnet portion,
wherein the electronic gear acts as a reducer.

20. A logistics processing system installed in a semiconductor manufacturing plant, the logistics processing system comprising:
a container transporting apparatus for transporting a container containing a plurality of substrates;
a container storage apparatus for storing the container therein; and
a control device configured to control each of the container transporting apparatus and the container storage apparatus,
wherein the container transporting apparatus includes:
a driving motor for generating a driving force;
a driving wheel for generating a rotational force and moving the container transporting apparatus under the rotational force;
a driving shaft for transmitting the driving force to the driving wheel; and
an electronic gear coupled to the driving shaft and the driving wheel, wherein the electronic gear is embodied as a non-contact gear using a magnet,
wherein the electronic gear includes:
a first core portion surrounding the driving shaft;
a first magnet portion surrounding the driving shaft and adjacent to the first core portion;
a second core portion surrounding the driving shaft and adjacent to the first magnet portion, wherein the second core portion includes a plurality of rods;
a second magnet portion surrounding the driving shaft and adjacent to the second core portion; and
a third core portion surrounding the driving shaft and adjacent to the second magnet portion,
wherein each of the plurality of rods extends in a direction different from a longitudinal direction of the driving shaft,
wherein a number of the plurality of rods is determined based on a number of pole pairs of the magnets included in the first magnet portion and a number of pole pairs of the magnets included in the second magnet portion,
wherein a rotation speed of the second magnet portion is determined based on a rotation speed of the first magnet portion, a number of pole pairs of the magnets included in the first magnet portion, and a number of pole pairs of the magnets included in the second magnet portion.
